(19) United States
(12) Patent Application Publication
(10) Pub. No.: US 2026/0113048 A1
(43) Pub. Date: Apr. 23, 2026

(54) ATOMIC OSCILLATOR

(71) Applicant: NEC Corporation, Tokyo (JP)

(72) Inventor: Kenta MATSUMOTO, Tokyo (JP)

(73) Assignee: NEC Corporation, Tokyo (JP)

(21) Appl. No.: 19/352,650

(22) Filed: Oct. 8, 2025

(30) Foreign Application Priority Data
Oct. 21, 2024 (JP) 2024-185072

(51) Int. Cl. H03L 7/26

(52) U.S. Cl. CPC H03L 7/26

(57) ABSTRACT

An atomic oscillator according to the present disclosure includes: two gas cells in which alkali metal atoms are encapsulated and to which bias magnetic fields are applied in opposite directions from each other; a light generating unit configured to apply irradiation light including at least two different frequency components to the both two gas cells; a light detecting unit configured to detect transmitted light passed through the two gas cells, respectively; and a control unit configured to determine a resonance frequency according to detection signals corresponding to the transmitted light detected from the two gas cells, respectively, and also control an oscillation frequency of an oscillation signal to be externally output according to the determined resonance frequency.

### INCORPORATION BY REFERENCE

This application is based upon and claims the benefit of priority from Japanese patent application No. 2024-185072, filed on Oct. 21, 2024, the disclosure of which is incorporated herein in its entirety by reference.

### TECHNICAL FIELD

The present disclosure relates to an atomic oscillator.

### BACKGROUND ART

An atomic oscillator that oscillates based on the energy transition of alkali metal atoms is known as an oscillator having long-term, highly accurate oscillation characteristics. The atomic oscillator determines a resonance frequency by detecting the transmitted light amount of light applied onto the atoms, and controls an oscillation frequency based on the resonance frequency. At this time, it is commonly practiced in the atomic oscillator to apply a bias magnetic field of several tens to several hundreds of microteslas (μT) and actuate in order to obtain a distinct resonance signal.

On the other hand, when the atomic oscillator is subjected to an external magnetic field variation, a magnetic field change occurs inside the atomic oscillator, and it is difficult to achieve improvement of the stability of the resonance frequency. Therefore, in the atomic oscillator, as described in Patent Literature 1, magnetic shielding and magnetic field cancellation are performed.
Patent Literature 1: Japanese Unexamined Patent Application Publication No. JP-A 2023-021719

However, it is difficult to completely shield and cancel an external magnetic field in an atomic oscillator. Thus, there arises a problem that it is difficult to achieve further improvement of the stability of the resonance frequency in an atomic oscillator due to a magnetic field change.

### SUMMARY OF THE INVENTION

An object of the present disclosure is to solve the abovementioned problem that it is difficult in an atomic oscillator to achieve further improvement of the stability of the resonance frequency against a magnetic field change.

An atomic oscillator as an aspect of the present invention includes: two gas cells in which alkali metal atoms are encapsulated and to which bias magnetic fields are applied in opposite directions from each other; a light generating unit configured to apply irradiation light including at least two different frequency components to the both two gas cells; a light detecting unit configured to detect transmitted light passed through the two gas cells, respectively; and a control unit configured to determine a resonance frequency according to detection signals corresponding to the transmitted light detected from the two gas cells, respectively, and also control an oscillation frequency of an oscillation signal to be externally output according to the determined resonance frequency.

Further, a control method of an atomic oscillator as an aspect of the present invention is a control method by an atomic oscillator which includes: two gas cells in which alkali metal atoms are encapsulated and to which bias magnetic fields are applied in opposite directions from each other; a light generating unit configured to apply irradiation light including at least two different frequency components to the both two gas cells; and a light detecting unit configured to detect transmitted light passed through the two gas cells, respectively. The control method includes: applying bias magnetic fields in opposite directions from each other to the two gas cells; and determining a resonance frequency according to detection signals corresponding to the transmitted light detected from the two gas cells, respectively, and also controlling an oscillation frequency of an oscillation signal to be externally output according to the determined resonance frequency.

With the configurations as described above, the present disclosure enables achievement of further improvement of the stability of the resonance frequency against a magnetic field change in an atomic oscillator.

### BRIEF DESCRIPTION OF DRAWINGS

FIG. 1 is a block diagram showing a configuration of an atomic oscillator in the present disclosure;

FIG. 2 is a diagram showing a state of processing by the atomic oscillator in the present disclosure;

FIG. 3 is a diagram showing a state of processing by the atomic oscillator in the present disclosure;

FIG. 4 is a flowchart showing processing operation by the atomic oscillator in the present disclosure;

FIG. 5 is a block diagram showing a configuration of an atomic oscillator in the present disclosure;

FIG. 6 is a flowchart showing processing operation by the atomic oscillator in the present disclosure;

FIG. 7 is a block diagram showing a configuration of an atomic oscillator in the present disclosure;

FIG. 8 is a diagram showing a state of processing by the atomic oscillator in the present disclosure;

FIG. 9 is a flowchart showing processing operation by the atomic oscillator in the present disclosure; and

FIG. 10 is a block diagram showing a configuration of an atomic oscillator in the present disclosure.

### EXAMPLE EMBODIMENTS

### First Example Embodiment

A first example embodiment of the present disclosure will be described with reference to the drawings. The drawings may be relevant to any of the example embodiments.

### [Configuration]

First, the overview of an atomic oscillator will be described. An atomic oscillator is a device that enables stable frequency oscillation using an atomic gas of alkali metal atoms or the like. An atomic oscillator has a gas cell in which an atomic gas is encapsulated, and by irradiating the gas cell with light that includes at least two different frequencies and measuring transmitted light thereof, is able to detect a quantum interference effect (called CPT (Coherent Population Trapping) resonance), which occurs when the transition frequency between specific quantum states of the atomic gas matches the difference frequency of the irradiation light, as a change in the transmitted light amount. For example, when a transmitted light spectrum in the case of detecting the transmitted light of cesium atoms is measured while the difference frequency of the irradiation light is swept, the transmitted light amount reaches a peak value when the difference frequency matches the transition frequency between the specific quantum states, and the CPT resonance is detected. The difference frequency of the irradiation light at this time is called a resonance frequency. By detecting the resonance frequency of the CPT resonance and controlling the difference frequency of the irradiation light in such a manner as to match the transition frequency between the specific quantum states, an atomic oscillator with high accuracy using a quantum interference effect can be realized. In the abovementioned atomic oscillator employing the CPT method, the resonance frequency of the CPT resonance is used as a reference for the oscillation frequency.

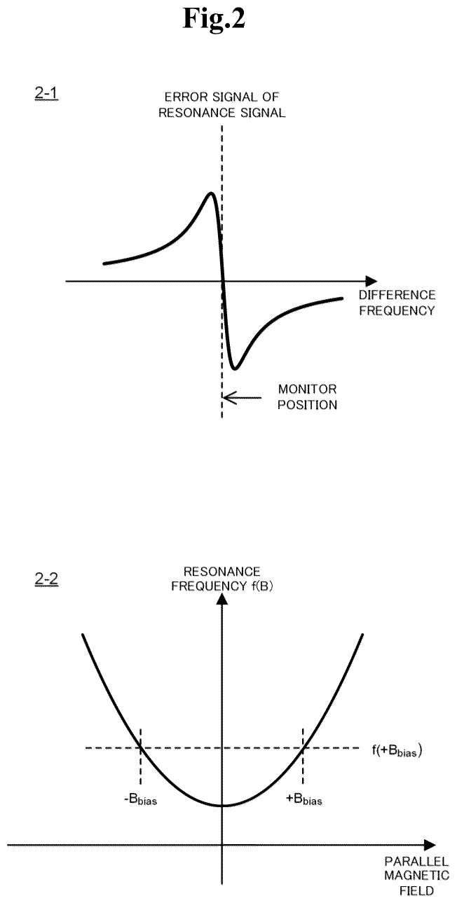

The transmitted light spectrum is expressed as a Lorentz function centered on the transition frequency between quantum states, and it is common practice to use a point where the transmitted light amount reaches the maximum as the resonance frequency of the CPT resonance, as a reference for the oscillation frequency. As an example, by sweeping the difference frequency of the irradiated light at the time of starting the atomic oscillator, it is possible to acquire the error signal of the transmitted light spectrum as in a schematic diagram shown in FIG. 2(2-1), and it is possible to use the zero-crossing point of the error signal as the reference for the oscillation frequency to be the resonance frequency. The error signal of the transmitted light spectrum can be acquired, for example, by modulating the difference frequency with a reference frequency having a period shorter than the sweep period of the difference frequency at the time of sweeping the difference frequency of the irradiation light, and performing lock-in detection of the detected transmitted light amount using the reference frequency.

The change rate of the error signal at the zero-crossing point that is the resonance frequency, that is, the ratio of the change of the error signal to the deviation between the difference frequency and the resonance frequency is defined as a zero-point slope. In the case of monitoring the error signal, as the absolute value of the zero-point slope is greater, the detection sensitivity of the difference between the difference frequency and the resonance frequency is higher.

In the atomic oscillator, after detection of the resonance frequency using the zero-crossing point as described above as an initialization process, it is possible to enhance the stability of an output frequency by constantly monitoring the zero-crossing point and applying feedback to a control signal of the oscillation device by the amount of deviation from the zero-crossing point.

In this example embodiment, the atomic oscillator is operated in a (0, 0) resonance state. A (0, 0) resonance frequency is expressed by a quadratic function of a magnetic field parallel to an optical axis as shown in FIG. 2(2-2), and a clear resonance signal cannot be obtained because another quantum level is not separated in a parallel magnetic field=0 μT. Therefore, the atomic oscillator in this example embodiment applies a bias magnetic field of several tens to several hundreds of microteslas to the gas cell, as will be described later.

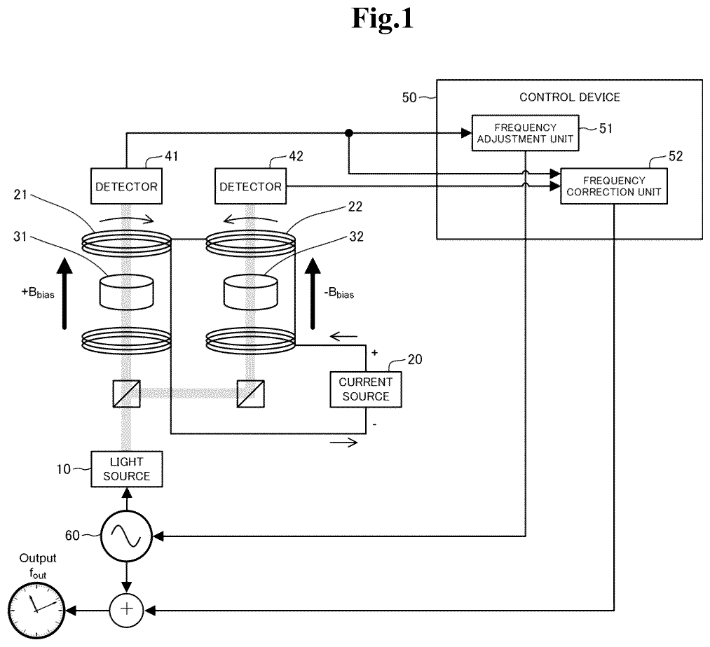

Subsequently, the configuration of the atomic oscillator in this example embodiment will be described. As shown in FIG. 1, the atomic oscillator includes a light source 10, magnetic field application devices 20, 21, and 22, gas cells 31 and 32, detectors 41 and 42, a control device 50, and an oscillation device 60. The control device 50 is configured with an information processing device equipped with an arithmetic logic unit and a memory unit. Then, the control device 50 includes a frequency adjustment unit 51 and a frequency correction unit 52 constructed by execution of a program by the arithmetic logic unit as shown in FIG. 1. In particular, in this example embodiment, the atomic oscillator includes two gas cells, and the magnetic field application devices 20, 21, and 22 and the detectors 41 and 42 are provided in correspondence with the two gas cells 31 and 32. The respective components will be described in detail below.

The light source 10 functions as a light generating unit and generates light having at least two different frequencies. Irradiation light, which is light generated by the light source 10, is applied to the two gas cell 31 and 32, respectively, and transmitted lights having passed through the two gas cells 31 and 32 respectively reach the two detectors 41 and 42, are detected, converted into electrical signals or the like, and sent to the control device 50. The light source 10 is configured in such a manner that the wavelength of the generated light, the intensity of the light for each frequency component, and the difference frequency are controlled based on a control signal by the control device 50.

The irradiation light that is light generated from the light source 10 has at least two different frequency components. The light generated from the light source 10 may have three or more different frequency components, but the difference frequency between two of the frequency components is substantially equal to the transition frequency between specific quantum states forming the CPT resonance of alkali metal atoms. For example, the light generated from a light generating unit 1 is realized by modulating single wavelength light oscillated from a semiconductor laser or the like using a frequency substantially equal to or 1/N times N, where N is an integer, the transition frequency of alkali metal atoms, thereby generating a sideband. At this time, control of the difference frequency is enabled by a mechanism that controls the modulation frequency. Alternatively, the light generated from the light generating unit 1 can be realized by combining two single wavelength lights oscillated from two semiconductor lasers or the like having a mechanism of controlling the difference frequency, for example.

Specifically, in this example embodiment, the light source 10 includes a vertical cavity surface emitting laser (VCSEL) as a light source element that generates single-wavelength excitation light, and generates two excitation lights by frequency modulation from the single-wavelength excitation light. Then, the excitation light generated by the light source 10 is branched and applied to the two gas cells 31 and 32, respectively. FIG. 1 shows a state of applying excitation lights to the two gas cells 31 and 32 in gray.

The two gas cells 31 and 32 are each configured with alkali metal atoms encapsulated therein. The alkali metal atoms encapsulated in the gas cells 31 and 32 may be cesium atoms, rubidium atoms, sodium atoms, or potassium atoms, for example. A material constituting the cases of the gas cells 31 and 32 is preferably a transparent material such as glass having a large transmittance of the irradiation light generated from the light source 10. In addition to alkali metal atoms, a buffer gas that does not contribute to the absorption of the irradiation light may be encapsulated in the gas cells 31 and 32 for the purpose of reducing the influence of collision between the container wall surface and gaseous alkali metal atom.

In this example embodiment, one gas cell 31 will be referred to as a main gas cell (first gas cell), and the other gas cell 32 will be referred to as a sub gas cell (second gas cell). Then, a system where the excitation light is applied to the main gas cell 31 will be referred to as a main system, and a system where the excitation light is applied to the sub gas cell 32 will be referred to as a sub system.

The magnetic field application devices 20, 21, and 22 include a current source 20 and coils 21 and 22. The coils 21 and 22 are arranged in the main system and the sub system, respectively, and include a main coil 21 arranged to cover the gas cell 31 of the main system and a sub coil 22 arranged to cover the gas cell 32 of the sub system. The current source 20 is connected to the coils 21 and 22 and configured to apply an electric current, and the direction and magnitude of the electric current are adjusted by the control device 50. Consequently, a bias magnetic field in a direction parallel or antiparallel to the irradiation light is generated at predetermined positions inside the gas cells 31 and 32, respectively.

Here, in this example embodiment, by applying electric current in the opposite directions to the main coil 21 and the sub coil 22, respectively, bias magnetic fields of the same intensity are applied to the main gas cell 31 and the sub gas cell 32 in the opposite directions. Consequently, as shown in FIG. 1, a bias magnetic field of +B_{bias} is applied to a predetermined position inside the main gas cell 31, and a bias magnetic field of −B_{bias} is applied to a predetermined position inside the sub gas cell 32.

The detectors 41 and 42 function as light detecting units, and detect transmitted light, which is transmitted light having passed through each of the gas cells 31 and 32. The detectors 41 and 42 can be enabled, for example, using photodiodes, but may be enabled using any photodetectors having a function of detecting light. To be specific, in this example embodiment, a main detector 41 arranged in the main system and detecting the transmitted light from the main gas cell 31, and a sub detector 42 arranged in the sub system and detecting the transmitted light from the sub gas cell 32 are included. Information of the light detected by each of the detectors 41 and 42 is converted into an electrical signal or the like, and input to the control device 50.

The frequency adjustment unit 51 included by the control device 50 (control unit) determines a resonance frequency from signals based on the transmitted light amounts input from the detectors 41 and 42, as an initialization process such as when starting the atomic oscillator, and controls an oscillation frequency by the oscillation device 60 based on the determined resonance frequency. To be specific, in this example embodiment, the frequency adjustment unit 51 sweeps the difference frequency of the irradiation light, determines a zero-crossing point at a monitor position for the error signal of the transmitted light spectrum based on the transmitted light having passed through the main gas cell 31 of the main system, as a resonance frequency as shown in FIG. 2(2-1), and after once determining the resonance frequency, applies feedback in such a manner that the error signal of the transmitted light spectrum obtained by lock-in detection is fixed at a predetermined signal level, and controls an oscillation frequency by adjusting the control voltage of the oscillation device 60. Here, the oscillation device 60 is configured with a VCXO (voltage control crystal oscillator) that oscillates at about 10 MHz, generates the oscillation signal in accordance with a control voltage output and applied by the frequency adjustment unit 51, and outputs it as the oscillation frequency, which is an external output of the atomic oscillator. Consequently, the oscillation frequency is stabilized to 10 MHz unless the resonance frequency changes. Further, the difference frequency of the irradiation light is generated by converting the oscillation signal of the VCXO into a signal of several GHz with a multiplier, and input to the light generating unit 1.

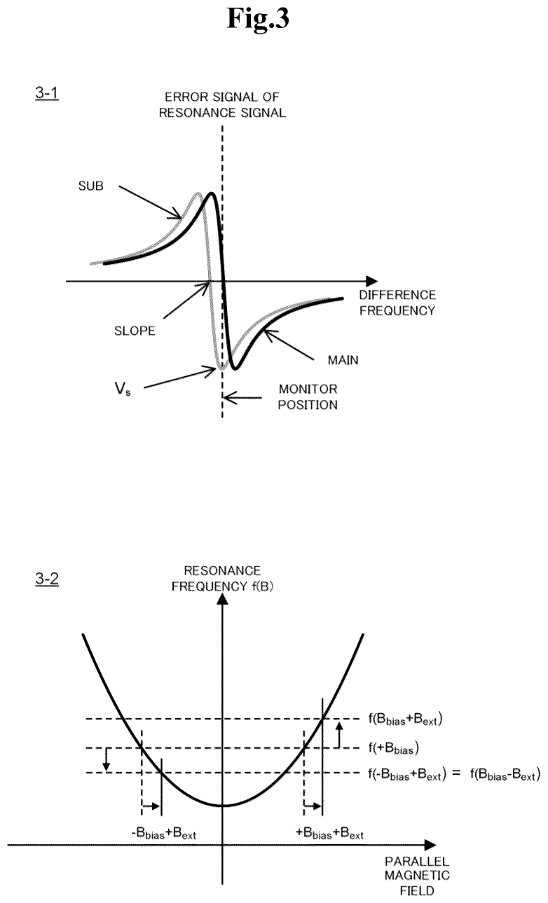

Here, a case where a penetration magnetic field, which is an external magnetic field other than the bias magnetic field, occurs in the atomic oscillator will be described. The penetration magnetic field is applied equivalently to both the main gas cell 31 and the sub gas cell 32, resulting in changes in the values of the magnetic fields at positions of the main gas cell 31 and sub gas cell 32, to which bias magnetic fields of the same intensity but in opposite directions are applied. Then, in the case of circularly polarized light irradiation, the resonance frequency is determined by the absolute value of the parallel magnetic field. For example, if |B_{bias} (bias magnetic field)|>|Bₑₓₜ (penetration magnetic field)|, then a magnetic field of |B_{bias}+Bₑₓₜ| is applied at the position of the main gas cell 31, and a magnetic field of |B_{bias}−Bₑₓₜ| is applied at the position of the sub gas cell 32. At this time, the bias magnetic field is several tens to several hundreds of microteslas (μT) and the earth magnetic field is several tens of microteslas (μT), and the above condition can be satisfied when the penetration magnetic field is blocked to about 1/1000. As an example, as shown in FIG. 3(3-2), in a case where a penetration magnetic field of “+Bₑₓₜ” occurs, a magnetic field of “+B_{bias}+Bₑₓₜ” is applied at the position of the main gas cell 31, and a magnetic field of “−B_{bias}+Bₑₓₜ” is applied at the position of the sub gas cell 32, so that the magnetic fields at the positions of the gas cells 31 and 32 change and differ. Then, as shown in FIG. 3(3-2), the (0, 0) resonance frequency is f(B_{bias}+Bₑₓₜ) at the main gas cell 31, and f(B_{bias}−Bₑₓₜ) at the sub gas cell 32, which means that the resonance frequencies are different between the main system and the sub system.

In the abovementioned situation, the frequency correction unit 52 monitors the error signal of the transmitted light spectrum having passed through the main gas cell 31 and the error signal of the transmitted light spectrum having passed through the sub gas cell 32, and detects whether a penetration magnetic field occurs. For example, the frequency correction unit 52 can detect the occurrence of a penetration magnetic field when, at the zero-crossing point of the error signal of the transmitted light spectrum having passed through the main gas cell 31, which is a monitor position, an error signal value Vₛ of the transmitted light spectrum having passed through the sub gas cell 32 is not at the zero-crossing point, that is, the error signal of the main gas cell 31 and the error signal of the sub gas cell 32 are different from each other. However, the frequency correction unit 52 may detect the difference between the error signal of the main gas cell 31 and the error signal of the sub gas cell 32 by another method based on the detection values, or may detect the occurrence of a penetration magnetic field by measuring an external magnetic field without using the detection values.

When detecting the occurrence of a penetration magnetic field, the frequency correction unit 52 corrects the oscillation frequency of an oscillation signal based on the resonance frequency determined based on the error signal of the transmission light spectrum of the main gas cell 31, with reference to the error signal of the transmission light spectrum detected from the sub gas cell 32. Here, the frequency correction unit 52 calculates in advance the zero-point slope of the error signal value from the sub gas cell 32 shown in FIG. 3(3-1) as the following Formula 1. At this time, a magnetic field change in the resonance frequency is represented by Formula 2, and when there is a penetration magnetic field Bₑₓₜ, a change at the monitor position (main resonance frequency) is represented by Formula 3, a change at the sub resonance frequency is represented by Formula 4, and the error signal value Vₛ of the sub gas cell 32 at the monitor position is represented by Formula 5.

$$\frac{d V}{d Δ f} \qquad [ Formula 1 ]$$

Δf: difference frequency−resonance frequency

$$\frac{df ( B )}{dB} ≅ \frac{df ( {B}_{bias} )}{dB} \qquad [ Formula 2 ]$$

$$\frac{df ( B )}{dB} {B}_{ext} \qquad [ Formula 3 ]$$

$$- \frac{df ( B )}{dB} {B}_{ext} \qquad [ Formula 4 ]$$

$${V}_{s} = - 2 \frac{dV}{d Δ f} \frac{df ( B )}{dB} {B}_{ext} \qquad [ Formula 5 ]$$

Then, a relative frequency change in the resonance frequency of the main gas cell 31 is represented by Formula 6, and the frequency correction unit 52 corrects the resonance frequency determined by the frequency adjustment unit 51 to an output frequency fₒᵤₜ as represented by Formula 7.

$$\frac{1}{{f}_{HFS}} \frac{df ( B )}{dB} {B}_{ext} = - \frac{{V}_{s}}{2 {f}_{HFS}} {( \frac{dV}{d Δ f} )}^{- 1} \qquad [ Formula 6 ]$$

f_{HFS}: transition frequency between ground levels of alkali metal atom

$${f}_{out} ( 1 + \frac{{V}_{s}}{2 {f}_{HFS}} {( \frac{dV}{d Δ f} )}^{- 1} ) \qquad [ Formula 7 ]$$

With the above configuration, the atomic oscillator in this example embodiment can estimate a penetration magnetic field based on the error signal of the transmitted light spectrum detected from the sub gas cell 32 serving as a sub system, and output an oscillation signal with an oscillation frequency obtained by correcting the resonance frequency in accordance with the penetration magnetic field. In the above, the occurrence of a penetration magnetic field is detected from the sub system and the resonance frequency is corrected, but the frequency correction unit 52 may always correct the resonance frequency based on the error signal from the sub gas cell 32 regardless of detection of a penetration magnetic field.

### [Operation]

Next, the operation of the abovementioned atomic oscillator will be described.

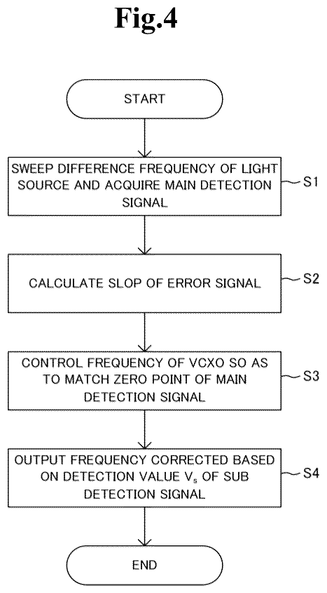

As a process for initialization such as startup of the atomic oscillator, the control device 50 sweeps the difference frequency of the irradiation light of the light source 10, and determines, as the resonance frequency, the zero-crossing point at the monitor position of the error signal of the transmitted light spectrum based on the transmitted light having passed through the main gas cell 31 of the main system (step S1 of FIG. 4). Further, as shown in FIG. 3(3-1), the control device 50 calculates the zero-point slope represented by Formula 1 in the error signal of the transmitted light spectrum based on the transmitted light having passed through the sub gas cell 32 of the sub system (step S2 of FIG. 4). Then, the control device 50 controls the oscillation frequency by adjusting the control voltage of the oscillation device 60 so that the error signal of the transmitted light spectrum detected from the main gas cell 31 matches the zero point as shown in FIG. 3(3-1) (step S3 of FIG. 4).

After that, the control device 50 controls in such a manner as to output an oscillation frequency with the resonance frequency being corrected in accordance with a penetration magnetic field, based on the error signal Vₛ of the transmitted light spectrum having passed through the sub gas cell 32 (step S4 of FIG. 4). To be specific, as shown in FIG. 3(3-1), in a case where the error signal of the main gas cell 31 is different from the error signal of the sub gas cell 32, the control device 50 detects the occurrence of a penetration magnetic field, and as represented by Formulas 3 to 7, based on the slope value of the error signal of the transmitted light spectrum detected from the sub gas cell 32 and the error signal value Vₛ at the monitor position, output an oscillation signal of an oscillation frequency with the resonance frequency determined from the error signal of the transmitted light spectrum of the main gas cell 31 being corrected.

As described above, the atomic oscillator in this example embodiment can output an oscillation signal of an oscillation frequency with the resonance frequency being corrected in accordance with the penetration magnetic field, based on the error signal of the transmitted light spectrum detected from the sub gas cell 32 serving as a sub system. As a result, it is possible to achieve further improvement of the stability of a resonance frequency against a magnetic field change in an atomic oscillator.

### Second Example Embodiment

Next, a second example embodiment of the present disclosure will be described with reference to the drawings. The drawings may be relevant to any of the example embodiments.

### [Configuration]

An atomic oscillator in this example embodiment is partially different in configuration from the atomic oscillator in the first example embodiment described above, and the different configuration will be mainly described in detail below.

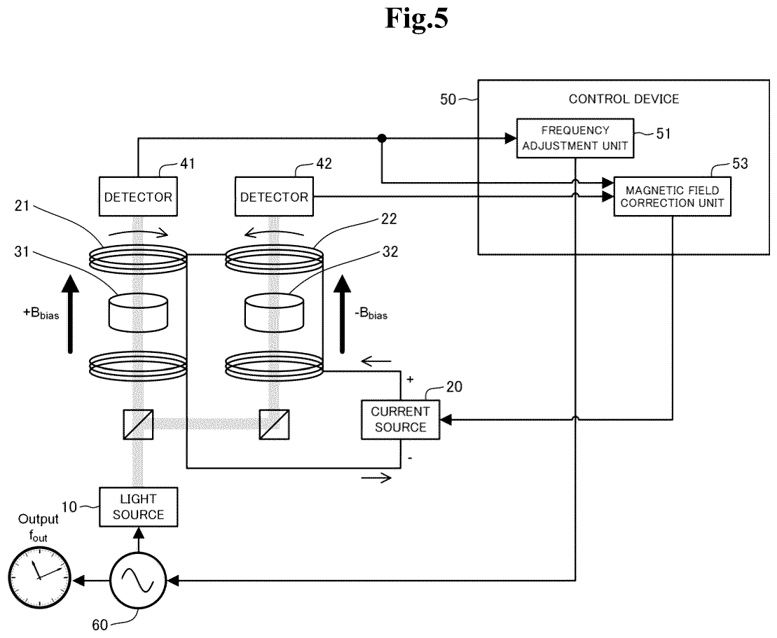

The atomic oscillator in this example embodiment includes the light source 10, the magnetic field application devices 20, 21, and 22, the gas cells 31 and 32, the detectors 41 and 42, the control device 50, and the oscillation device 60, as shown in FIG. 5. The control device 50 includes the frequency adjustment unit 51 and a magnetic field correction unit 53 constructed by execution of the program by the arithmetic logic unit as shown in FIG. 1. The respective components will be described in detail below.

The atomic oscillator includes, as described above, the two gas cells 31 and 32 (the main gas cell 31 and the sub gas cell 32), which configure the main system and the sub system, respectively. Then, as described above, bias magnetic fields of the same intensity are applied in the opposite directions to the gas cells 31 and 32 by the coils 21 and 22 of the magnetic field application devices 20, 21, and 22. Consequently, a bias magnetic field of +B_{bias} is applied at a predetermined position inside the main gas cell 31, and a bias magnetic field of −B_{bias} is applied at a predetermined position inside the sub gas cell 32. In a case where a penetration magnetic field is applied to the atomic oscillator, a magnetic field of +B_{bias}+Bₑₓₜ is applied at a predetermined position inside the main gas cell 31, and a magnetic field of −B_{bias}+Bₑₓₜ is applied at a predetermined position inside the sub gas cell 32.

The frequency adjustment unit 51 included by the control device 50 (control unit), as described above, sweeps the difference frequency of the irradiation light and determines, as the resonance frequency, the zero-crossing point at the monitor position of the error signal of the transmitted light spectrum based on the transmitted light having passed through the main gas cell 31 of the main system, and after once determining the resonance frequency, applies feedback so as to fix the error signal of the transmitted light spectrum obtained by lock-in detection to a predetermined signal level and controls the oscillation frequency by adjusting the control voltage of the oscillation device 60. As will be described later, even if a bias magnetic field applied to the gas cells 31 and 32 is corrected as a penetration magnetic field is applied, the control device 50 determines the resonance frequency from the error signal of the transmitted light spectrum based on the transmitted light having passed through the main gas cell 31 of the main system in such a situation, and controls the oscillation frequency

The magnetic field correction unit 53 included by the control device 50 (control unit), as in the first example embodiment described above, monitors the error signal of the transmitted light spectrum having passed through the main gas cell 31 and the error signal of the transmitted light spectrum having passed through the sub gas cell 32, and detects whether a penetration magnetic field has occurred. For example, the magnetic field correction unit 53 can detect the occurrence of a penetration magnetic field when, at the zero-crossing point of the error signal of transmitted light spectrum having passed through the main gas cell 31, which is the monitor position, the error signal value Vs of the transmitted light spectrum having passed through the sub gas cell 32 is not at the zero-crossing point of the error signal, that is, the error signal of the main gas cell 31 and the error signal of the sub gas cell 32 are different from each other. However, the magnetic field correction unit 53 may detect the difference between the error signal of the main gas cell 31 and the error signal of the sub gas cell 32 by another method based on detection values thereof, or may detect the occurrence of a penetration magnetic field by measuring an external magnetic field without using the detection values.

When detecting the occurrence of a penetration magnetic field, the magnetic field correction unit 53 controls so as to change the intensity of the bias magnetic field based on the error signal of the transmitted light spectrum detected from the sub gas cell 32. At this time, the magnetic field correction unit 53 controls the value of an electric current applied to the current source 20 of the magnetic field application devices 20, 21, and 22 in such a manner that a magnetic field intensity “+B_{bias}+Bₑₓₜ” at a predetermined position inside the main gas cell 31 is kept constant, thereby changing the intensity of the magnetic field applied by the coil 21.

To be specific, the magnetic field correction unit 53 corrects the magnetic field in the following manner. First, a magnetic field at the time of startup of the atomic oscillator is represented by Formula 8, and an error signal value of the sub gas cell 32 when a penetration magnetic field is not applied and there is no magnetic field change is represented by Formula 9. Then, when a penetration magnetic field is applied and an error signal value of the sub gas cell 32 at the time of magnetic field change is as represented by Formula 10, the penetration magnetic field can be estimated by Formula 11. Therefore, the magnetic field correction unit 53 corrects the bias magnetic field as shown in Formula 12. As shown in Formula 12, in order to correct the bias magnetic field, the slope of an error signal represented by Formula 1 will be calculated in the same manner as described above, and data representing a magnetic field change in the resonance frequency represented by Formula 2 and shown in FIG. 2(2-2) will be stored in advance.

$${B}_{bias , 0} + {B}_{ext , 0} \qquad [ Formula 8 ]$$

$${V}_{s , 0} = - 2 \frac{dV}{d Δ f} \frac{df ( B )}{dB} {B}_{ext , 0} \qquad [ Formula 9 ]$$

$${V}_{s} ( t ) = {V}_{s , 0} + δ V \qquad [ Formula 10 ]$$

$${B}_{ext} ( t ) = {B}_{ext , 0} + δ {B}_{ext} = - \frac{1}{2} {( \frac{dV}{dΔf} \frac{df ( B )}{dB} )}^{- 1} ( {V}_{s , 0} + δ V ) \qquad [ Formula 11 ]$$

$${B}_{bias , 0} - δ {B}_{ext} = {B}_{bias , 0} + \frac{1}{2} {( \frac{dV}{d Δ f} \frac{df ( B )}{dB} )}^{- 1} δ V \qquad [ Formula 12 ]$$

With the above configuration, in the atomic oscillator in this example embodiment, a penetration magnetic field is estimated based on the error signal of the transmitted light spectrum detected from the sub gas cell 32 serving as a sub system, and the bias magnetic field is corrected in such a manner as to cancel the penetration magnetic field. Then, the atomic oscillator can determine the resonance frequency in accordance with the error signal from the main gas cell 31 in the corrected magnetic field, and output an oscillation signal of an oscillation frequency based on the determined resonance frequency. In the above, the occurrence of a penetration magnetic field is detected from the sub system and the magnetic field is corrected, but the magnetic field correction unit 53 may correct the magnetic field based on the error signal from the sub gas cell 32 at all times regardless of detection of a penetration magnetic field.

### [Operation]

Next, the operation of the aforementioned atomic oscillator will be described.

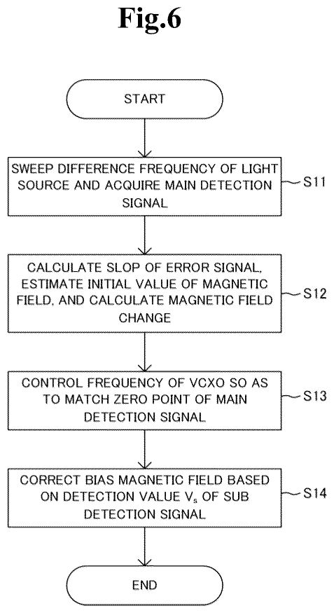

As an initialization process at startup of the atomic oscillator, the control device 50 sweeps the difference frequency of the irradiation light of the light source 10, and determines, as the resonance frequency, the zero-crossing point at the monitor position of the error signal of the transmission light spectrum based on the transmission light having passed through the main gas cell 31 of the main system (step S11 in FIG. 6). Further, as shown in FIG. 3(3-1), the control device 50 calculates in advance the zero-point slope indicated in Formula 1 in the error signal of the transmitted light spectrum based on the transmitted light having passed through the sub gas cell 32 of the sub system (step S12 of FIG. 6). Furthermore, the control device 50 estimates the initial value of the magnetic field indicated in Formula 8, and calculates a magnetic field change from the data of a magnetic field change of resonance frequency as indicated by Formula 2 and shown in FIG. 2(2-2) (step S12 of FIG. 6). Then, the control device 50 controls the oscillation frequency by adjusting the control voltage of the oscillation device 60 in such a manner that the error signal of the transmitted light spectrum detected from the main gas cell 31 matches the zero point as shown in FIG. 3(3-1) (step S13 of FIG. 6).

Subsequently, the control device 50 controls the value of an electric current applied to the current source 20 of the magnetic field application device in such a manner as to correct the magnetic field in accordance with the penetration magnetic field, based on the error signal of the transmitted light spectrum having passed through the sub gas cell 32 (step S14 of FIG. 6). To be specific, as shown in FIG. 3(3-1), when the error signal of the main gas cell 31 is different from the error signal of the sub gas cell 32, the control device 50 detects the occurrence of a penetration magnetic field, and applies a corrected magnetic field based on the slope value of the error signal of the transmitted light spectrum detected from the sub gas cell 32 and a magnetic field change, as indicated in Formulas 9 to 12. Then, the control device 50 outputs an oscillation signal of at an oscillation frequency based on the resonance frequency determined from the error signal of the transmitted light spectrum of the main gas cell 31 in the corrected magnetic field.

As described above, the atomic oscillator according to this example embodiment can, based on the error signal of the transmitted light spectrum detected from the sub gas cell 32 serving as a sub system, correct the magnetic field applied to the main gas cell 31 in accordance with the penetration magnetic field, and output an oscillation signal of an oscillation frequency corresponding to the resonance frequency detected under the environment of the corrected magnetic field. As a result, it is possible to achieve further improvement of the stability of the resonance frequency with respect to a magnetic field change in an atomic oscillator.

### Third Example Embodiment

Next, a third example embodiment of the present disclosure will be described with reference to the drawings. The drawings may be relevant to any of the example embodiments.

### [Configuration]

An atomic oscillator in this example embodiment differs in part of its configuration from the atomic oscillators in the first and second example embodiments described above, and the differing configuration will be mainly described in detail below.

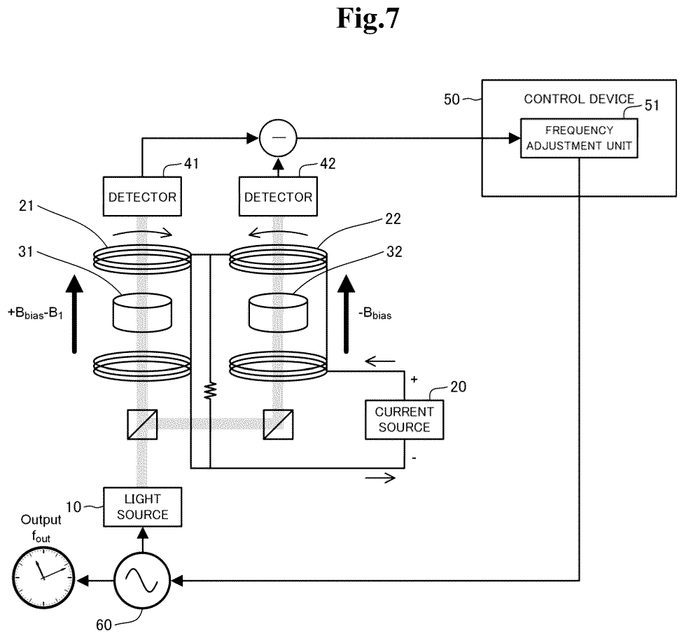

The atomic oscillator according to this example embodiment includes the light source 10, the magnetic field application devices 20, 21, and 22, the gas cells 31 and 32, the detectors 41 and 42, the control device 50, and the oscillation device 60, as shown in FIG. 7. As shown in FIG. 1, the control device 50 includes the frequency adjustment unit 51 constructed by execution of a program by the arithmetic logic unit. The respective components will be described in detail below.

The atomic oscillator includes, in the same manner as described above, the two gas cells 31 and 32 (main gas cell 31 and sub gas cell 32), which constitute the main system and the sub system, respectively. To the gas cells 31 and 32, bias magnetic fields are applied in opposite directions, respectively, by the coils 21 and 22 of the magnetic field application devices 20, 21, and 22 in the same manner as described above. However, in this example embodiment, bias magnetic fields of different intensities are applied to the gas cells 31 and 32, respectively. For example, by inserting a parallel resistor as shown in FIG. 7 or reducing the number of coil turns regarding the main coil 21 of the magnetic field application device, a difference B1 is created in the intensities of the bias magnetic fields applied to the gas cell 31 and 32 by the main coil 21 and the sub coil 22, respectively. Consequently, a bias magnetic field of +B_{bias}−B₁ is applied to a predetermined position inside the main gas cell 31, and a bias magnetic field of −B_{bias} is applied to a predetermined position inside the sub gas cell 32. However, the method is not limited to the one described above, and any method may be employed to create a difference in the intensities of the magnetic fields applied to the gas cells 31 and 32.

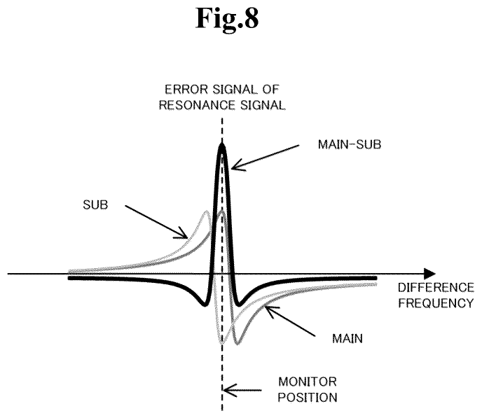

In this example embodiment, as shown in FIG. 7, the atomic oscillator is configured in such a manner that a difference signal representing the difference between the error signal of the transmitted light spectrum having passed through the main gas cell 31 and detected by the detector 41 and the error signal of the transmitted light spectrum having passed through the sub gas cell 32 and detected by the detector 42 is input to the control device 50. In this example embodiment, as described above, bias magnetic fields of different intensities are applied to the gas cells 31 and 32 even in the absence of an applied penetration magnetic field, so that there is a difference in the error signals (main, sub) between the main gas cell 31 and the sub gas cell 32 as shown in FIG. 8, there is a difference in the resonance frequencies determinable from these error signals. Furthermore, when a penetration magnetic field is applied, bias magnetic fields are applied in opposite directions to the gas cell 31 and 32, respectively, thereby causing an additional difference in the resonance frequencies determinable from the error signals.

In the aforementioned situation, the frequency adjustment unit 51 included by the control device 50 (control unit) according to this example embodiment determines a resonance frequency based on the difference signal between the error signal of the transmitted light spectrum having passed through the main gas cell 31 and the error signal of the transmitted light spectrum having passed through the sub gas cell 32, and controls the oscillation frequency of an oscillation signal based on the determined resonance frequency. To be specific, the frequency adjustment unit 51 sweeps the difference frequency of the irradiation light, and as shown in FIG. 8, determines the center (peak) of the difference signal between the error signal of the transmitted light spectrum detected from the main gas cell 31 and the error signal of the transmitted light spectrum detected from the sub gas cell 32, as the resonance frequency. Then, the frequency adjustment unit 51 locks the center (peak) of the difference signal as the resonance frequency, and controls the oscillation frequency by adjusting the control voltage of the oscillation device 60. At this time, even when a penetration magnetic field is applied, the peak of the difference signal tends to remain stationary, resulting in frequency stability against a magnetic field change.

It is desirable that the difference B₁ in the magnetic field be greater than twice the maximum value of the assumed penetration magnetic field Bₑₓₜ. For example, when Bₑₓₜ=B1/2, the resonance frequencies due to the main error signal and the sub error signal overlaps, which may cause the difference signal to disappear.

### [Operation]

Next, the operation of the aforementioned atomic oscillator will be described.

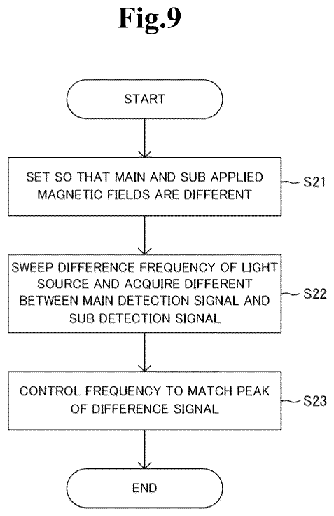

First, the atomic oscillator is set in such a manner that bias magnetic fields of opposite directions to each other and different intensities from each other are applied to the respective gas cells 31 and 32 (step S21 of FIG. 9). In such a configuration, the control device 50 sweeps the difference frequency of irradiation light and acquires a difference signal between an error signal of a transmitted light spectrum detected from the main gas cell 31 and an error signal of a transmitted light spectrum detected from the sub gas cell 32 (step S22 of FIG. 9). Then, the control device 50 determines the center (peak) of the difference signal as a resonance frequency, and controls an oscillation frequency by adjusting the control voltage of the oscillation device 60 (step S23 of FIG. 9).

As described above, in this example embodiment, the atomic oscillator can provide a difference in magnetic fields applied to the gas cells 31 and 32, and output an oscillation signal determined from the error signal of the transmitted light spectrums detected from the gas cells 31 and 32, respectively. As a result, it is possible to achieve further improvement of the stability of the resonance frequency with respect to a magnetic field change in an atomic oscillator.

### Fourth Example Embodiment

Next, a fourth example embodiment of the present disclosure will be described. The drawings may be relevant to any of the example embodiments.

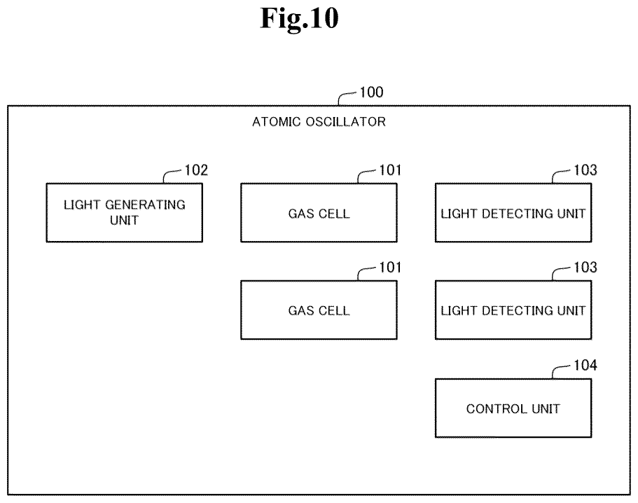

As shown in FIG. 10, an atomic oscillator 100 in this example embodiment includes:
two gas cells 101 in which alkali metal atoms are encapsulated and to which bias magnetic fields are applied in opposite directions from each other;
a light generating unit 102 that irradiates the two gas cells with irradiation light having at least two different frequency components;
a light detecting unit 103 that detects transmitted light passed through the two gas cells, respectively; and
a control unit 104 that determines a resonance frequency based on detection signals corresponding to the transmitted light detected respectively from the two gas cells, and controls an oscillation frequency of an oscillation signal externally output based on the determined resonance frequency.

According to the above configuration, the atomic oscillator 100 determines a resonance frequency and controls an oscillation frequency, based on the detection signals of the transmitted light from the two gas cell cells 101 to which bias magnetic fields are applied in opposite directions. Consequently, it is possible to detect the application of a penetration magnetic field from the transmitted light, to correct the resonance frequency in accordance with the penetration magnetic field or correct the magnetic field, or to suppress the influence of a magnetic field change due to the penetration magnetic field, thereby determining the resonance frequency. As a result, it is possible to achieve further improvement of the stability of the resonance frequency against a magnetic field change.

Although the present disclosure has been described above with reference to the above-described example embodiments, the present disclosure is not limited to the example embodiments described above. The configuration of the present disclosure can be changed in various manners that can be understood by those skilled in the art within the scope of the present disclosure.

### <Supplementary Notes>

The whole or part of the example embodiments disclosed above can be described as the following supplementary notes. Below, the overview of the configurations of the atomic oscillator and the control method according to the present disclosure will be described. However, the present invention is not limited to the following configurations.

Some or all of configurations described in Supplementary Notes 2 to 7 dependent on Supplementary Note 1 below and functions by the configurations may be dependent on other Supplementary Note 8 by the same dependence as Supplementary Notes 2 to 7. Furthermore, not limited to Supplementary Notes 1 and 8, within the scope of the example embodiment described above, some or all of the configurations described as supplementary notes and functions by such configurations may be dependent on hardware, software, various recording means for recording software, or system.

### (Supplementary Note 1)

An atomic oscillator comprising:
two gas cells in which alkali metal atoms are encapsulated and to which bias magnetic fields are applied in opposite directions from each other;
a light generating unit configured to apply irradiation light including at least two different frequency components to the both two gas cells;
a light detecting unit configured to detect transmitted light passed through the two gas cells, respectively; and
a control unit configured to determine a resonance frequency according to detection signals corresponding to the transmitted light detected from the two gas cells, respectively, and also control an oscillation frequency of an oscillation signal to be externally output according to the determined resonance frequency.

### (Supplementary Note 2)

The atomic oscillator according to supplementary note 1, wherein
to the two gas cells, the bias magnetic fields of same intensity are applied in opposite directions from each other.

### (Supplementary Note 3)

The atomic oscillator according to supplementary note 2, wherein
the control unit is configured to, when the detection signals respectively detected from the two gas cells are different, determine a resonance frequency according to the detection signals respectively detected from the two gas cells, and also control an oscillation frequency of an oscillation signal to be externally output according to the determined resonance frequency.

### (Supplementary Note 4)

The atomic oscillator according to supplementary note 2, wherein
the control unit is configured to determine a resonance frequency according to the detection signal detected from a first one of the gas cells, and correct an oscillation frequency of an oscillation signal based on the resonance frequency according to the detection signal detected from a second one of the gas cells.

### (Supplementary Note 5)

The atomic oscillator according to supplementary note 2, wherein
the control unit is configured to correct the intensity of the bias magnetic fields according to the detection signal detected from a second one of the gas cells, and also determine a resonance frequency according to the detection signal detected from a first one of the gas cells and control an oscillation frequency of an oscillation signal.

### (Supplementary Note 6)

The atomic oscillator according to supplementary note 1, wherein
to the two gas cells, the bias magnetic fields of different intensities are applied in opposite directions from each other.

### (Supplementary Note 7)

The atomic oscillator according to supplementary note 6, wherein
the control unit is configured to determine a resonance frequency according to a difference between the detection signals detected from the two gas cells, respectively, and also control an oscillation frequency of an oscillation signal to be externally output according to the determined resonance frequency.

### (Supplementary Note 8)

A control method by an atomic oscillator, the atomic oscillator including:
two gas cells in which alkali metal atoms are encapsulated and to which bias magnetic fields are applied in opposite directions from each other;
a light generating unit configured to apply irradiation light including at least two different frequency components to the both two gas cells; and
a light detecting unit configured to detect transmitted light passed through the two gas cells, respectively, the control method comprising:
applying bias magnetic fields in opposite directions from each other to the two gas cells; and
determining a resonance frequency according to detection signals corresponding to the transmitted light detected from the two gas cells, respectively, and also controlling an oscillation frequency of an oscillation signal to be externally output according to the determined resonance frequency.

### (Supplementary Note 9)

The control method according to supplementary note 8, comprising
applying the bias magnetic fields of same intensity in opposite directions from each other to the two gas cells.

### (Supplementary Note 10)

The control method according to supplementary note 9, comprising
when the detection signals respectively detected from the two gas cells are different, determining a resonance frequency according to the detection signals respectively detected from the two gas cells, and also controlling an oscillation frequency of an oscillation signal to be externally output according to the determined resonance frequency.

### (Supplementary Note 11)

The control method according to supplementary note 9, comprising
determining a resonance frequency according to the detection signal detected from a first one of the gas cells, and correcting an oscillation frequency of an oscillation signal based on the resonance frequency according to the detection signal detected from a second one of the gas cells.

### (Supplementary Note 12)

The control method according to supplementary note 9, comprising
correcting the intensity of the bias magnetic fields according to the detection signal detected from a second one of the gas cells, and also determining a resonance frequency according to the detection signal detected from a first one of the gas cells and controlling an oscillation frequency of an oscillation signal.

### (Supplementary Note 13)

The control method according to supplementary note 8, comprising
applying the bias magnetic fields of different intensities in opposite directions from each other to the two gas cells.

### (Supplementary Note 14)

The control method according to supplementary note 13, comprising
determining a resonance frequency according to a difference between the detection signals detected from the two gas cells, respectively, and also controlling an oscillation frequency of an oscillation signal to be externally output according to the determined resonance frequency.

### DESCRIPTION OF REFERENCE NUMERALS

10 light source
20 current source
21, 22 coil
31, 32 gas cell
41, 42 detector
50 control device
52 frequency adjustment unit
52 frequency correction unit
53 magnetic field correction unit
60 oscillation device
100 atomic oscillator
101 gas cell
102 light generating unit
103 light detecting unit
104 control unit

1. An atomic oscillator comprising:
two gas cells in which alkali metal atoms are encapsulated and to which bias magnetic fields are applied in opposite directions from each other;
a light generating unit configured to apply irradiation light including at least two different frequency components to the both two gas cells;
a light detecting unit configured to detect transmitted light passed through the two gas cells, respectively; and
a control unit configured to determine a resonance frequency according to detection signals corresponding to the transmitted light detected from the two gas cells, respectively, and also control an oscillation frequency of an oscillation signal to be externally output according to the determined resonance frequency.

2. The atomic oscillator according to claim 1, wherein
to the two gas cells, the bias magnetic fields of same intensity are applied in opposite directions from each other.

3. The atomic oscillator according to claim 2, wherein
the control unit is configured to, when the detection signals respectively detected from the two gas cells are different, determine a resonance frequency according to the detection signals respectively detected from the two gas cells, and also control an oscillation frequency of an oscillation signal to be externally output according to the determined resonance frequency.

4. The atomic oscillator according to claim 2, wherein
the control unit is configured to determine a resonance frequency according to the detection signal detected from a first one of the gas cells, and correct an oscillation frequency of an oscillation signal based on the resonance frequency according to the detection signal detected from a second one of the gas cells.

5. The atomic oscillator according to claim 2, wherein
the control unit is configured to correct the intensity of the bias magnetic fields according to the detection signal detected from a second one of the gas cells, and also determine a resonance frequency according to the detection signal detected from a first one of the gas cells and control an oscillation frequency of an oscillation signal.

6. The atomic oscillator according to claim 1, wherein
to the two gas cells, the bias magnetic fields of different intensities are applied in opposite directions from each other.

7. The atomic oscillator according to claim 6, wherein
the control unit is configured to determine a resonance frequency according to a difference between the detection signals detected from the two gas cells, respectively, and also control an oscillation frequency of an oscillation signal to be externally output according to the determined resonance frequency.

8. A control method by an atomic oscillator, the atomic oscillator including:
two gas cells in which alkali metal atoms are encapsulated and to which bias magnetic fields are applied in opposite directions from each other;
a light generating unit configured to apply irradiation light including at least two different frequency components to both the two gas cells; and
a light detecting unit configured to detect transmitted light passed through the two gas cells, respectively, the control method comprising:
applying bias magnetic fields in opposite directions from each other to the two gas cells; and
determining a resonance frequency according to detection signals corresponding to the transmitted light detected from the two gas cells, respectively, and also controlling an oscillation frequency of an oscillation signal to be externally output according to the determined resonance frequency.

9. The control method according to claim 8, comprising
applying the bias magnetic fields of same intensity in opposite directions from each other to the two gas cells.

10. The control method according to claim 9, comprising
when the detection signals respectively detected from the two gas cells are different, determining a resonance frequency according to the detection signals respectively detected from the two gas cells, and also controlling an oscillation frequency of an oscillation signal to be externally output according to the determined resonance frequency.

11. The control method according to claim 9, comprising
determining a resonance frequency according to the detection signal detected from a first one of the gas cells, and correcting an oscillation frequency of an oscillation signal based on the resonance frequency according to the detection signal detected from a second one of the gas cells.

12. The control method according to claim 9, comprising
correcting the intensity of the bias magnetic fields according to the detection signal detected from a second one of the gas cells, and also determining a resonance frequency according to the detection signal detected from a first one of the gas cells and controlling an oscillation frequency of an oscillation signal.

13. The control method according to claim 8, comprising
applying the bias magnetic fields of different intensities in opposite directions from each other to the two gas cells.

14. The control method according to claim 13, comprising
determining a resonance frequency according to a difference between the detection signals detected from the two gas cells, respectively, and also controlling an oscillation frequency of an oscillation signal to be externally output according to the determined resonance frequency.
